(19) United States
(12) Patent Application Publication
(10) Pub. No.: US 2025/0210932 A1
(43) Pub. Date: Jun. 26, 2025

(54) SEMICONDUCTOR LASER LIGHT SOURCE DEVICE

(71) Applicant: Mitsubishi Electric Corporation, Tokyo (JP)

(72) Inventor: Hayata FUKUSHIMA, Tokyo (JP)

(73) Assignee: Mitsubishi Electric Corporation, Tokyo (JP)

(21) Appl. No.: 18/852,234

(22) PCT Filed: Jul. 19, 2022
(86) PCT No.: PCT/JP2022/027979

§ 371 Date: Sep. 27, 2024

(51) Int. Cl. H01S 5/02315; H01S 5/0231; H01S 5/02345; H01S 5/026

(52) U.S. Cl. CPC H01S 5/02315; H01S 5/0231; H01S 5/02345; H01S 5/0262

(57) ABSTRACT

A semiconductor laser light source device includes a metal stem; a first support block provided on the metal stem and is electrically conductive; a temperature control module provided on the metal stem; a second support block provided on the temperature control module and is electrically conductive; a first substrate provided on a first side surface of the first support block; a second substrate provided on a second side surface of the second support bloc; a photosemiconductor chip provided on the second substrate; an electrically conductive cap provided on the metal stem and covers the first support block, the temperature control module, the second support block, the first substrate, the second substrate, and the photosemiconductor chip; and a metal block provided between the second support block and the cap.

### FIELD

The present disclosure relates to a semiconductor laser light source device.

### BACKGROUND

PTL 1 discloses a semiconductor optical modulator having a metal stem. A first support block and a temperature control module are mounted on the metal stem. A first dielectric substrate is mounted on a side surface of the first support block. A second support block is mounted on the temperature control module. The semiconductor optical modulation apparatus is mounted on a second dielectric substrate.

### CITATION LIST

### Patent Literature

[PTL 1] JP 5188625 B

### SUMMARY

### Technical Problem

SNSs (social networking services), video sharing services, and so forth have been spreading on a world wide scale, and capacity enlargement for data transmission has been accelerated. In order to cope with high-speed and capacity enlargement for signals in a limited mounting space, there has been a need for an increase in speed and a reduction in size and cost of an optical transceiver. As a structure of a semiconductor laser light source device on which a semiconductor optical modulation apparatus is mounted, it is a common practice to adopt a TO-CAN (transistor-outlined CAN) type, which can be introduced as a product inexpensively. In the TO-CAN type, in general, lead pins are sealed in and fixed to a metal stem by using glass. In such sealing and fixing, pressures due to differences among thermal expansion coefficients of members are used. Thus, in order to secure high airtightness, arrangement of the lead pins and an interval between the lead pins are important. Further, members which form the semiconductor laser light source device can basically be mounted only on the metal stem. As described above, for a TO-CAN type semiconductor laser light source device, it is necessary to achieve an increase in speed and cost reduction under a number of structural constraints.

In a case where an EAM-LD (electro-absorption modulator laser diode) is used, for example, as the semiconductor optical modulation apparatus, it is preferable in order to suppress degradation of frequency response characteristics that a stable reference potential be given for a signal line. Accordingly, resonance in a band can be suppressed. Here, the semiconductor optical modulation apparatus experiences a change in an oscillation wavelength or an optical output due to its heat generation. In a laser light source device in PTL 1, a temperature control module is used for maintaining a constant temperature of the semiconductor optical modulation apparatus. In such a structure, for example, a potential of a member such as a support block which is mounted on the temperature control module might become high with respect to the reference potential. In this case, particularly in a case where a signal with 20 Gbps or greater is transmitted, the signal is discharged while being propagated through a CAN internal portion, from a structure at a higher potential than the reference potential to a structure at a low potential. This possibly causes degradation of frequency response characteristics due to resonance.

An object of the present disclosure is to obtain a semiconductor laser light source device capable of improving high frequency characteristics.

### Solution to Problem

A semiconductor laser light source device according to this disclosure includes a metal stem; a first support block which is provided on a main surface of the metal stem and is electrically conductive; a temperature control module which has an upper surface and a back surface on an opposite side to the upper surface, the back surface being provided on the main surface of the metal stem; a second support block which is provided on the upper surface of the temperature control module and is electrically conductive; a first substrate which is provided on a first side surface of the first support block and in which a signal line is formed; a second substrate which is provided on a second side surface of the second support block and in which a signal line is formed; a photosemiconductor chip which is provided on the second substrate; an electrically conductive cap which is provided on the main surface of the metal stem and covers the first support block, the temperature control module, the second support block, the first substrate, the second substrate, and the photosemiconductor chip; and a metal block which is provided between the second support block and the cap.

### Advantageous Effects of Invention

In a semiconductor laser light source device according to the present disclosure, a signal which is discharged from a second support block or a temperature control module to the space can be absorbed by a metal block. Accordingly, resonance can be suppressed, and high frequency characteristics can be improved.

### BRIEF DESCRIPTION OF DRAWINGS

FIG. 1 is a front perspective view of a semiconductor laser light source device according to a first embodiment.

FIG. 2 is a plan view of the semiconductor laser light source device according to the first embodiment.

FIG. 3 is a side view of the semiconductor laser light source device according to the first embodiment.

FIG. 4 is a rear perspective view of the semiconductor laser light source device according to the first embodiment.

FIG. 5 is an outline diagram of the semiconductor laser light source device according to the first embodiment.

FIG. 6 is a graph representing the frequency response characteristics in cases where the cap is present in a semiconductor laser light source device according to a comparative example and where no cap is present.

FIG. 7 is a graph representing the frequency response characteristics of the semiconductor laser light source device according to the first embodiment and of the semiconductor laser light source device according to the comparative example.

FIG. 8 is graph representing the frequency response characteristics of a semiconductor laser light source device according to a modification of the first embodiment and of the semiconductor laser light source device according to the comparative example.

FIG. 9 is graph representing the frequency response characteristics of a semiconductor laser light source device according to a modification of the first embodiment and of the semiconductor laser light source device according to the comparative example.

FIG. 10 is a rear perspective view of a semiconductor laser light source device according to a second embodiment.

FIG. 11 is a plan view of the semiconductor laser light source device according to the second embodiment.

FIG. 12 is a side view of the semiconductor laser light source device according to the second embodiment.

FIG. 13 is a graph representing the frequency response characteristics of the semiconductor laser light source device according to the second embodiment and of a semiconductor laser light source device according to a comparative example.

FIG. 14 is a rear perspective view of a semiconductor laser light source device according to a third embodiment.

FIG. 15 is a plan view of the semiconductor laser light source device according to the third embodiment.

FIG. 16 is a side view of the semiconductor laser light source device according to the third embodiment.

FIG. 17 is a graph representing the frequency response characteristics of the semiconductor laser light source device according to the third embodiment and of a semiconductor laser light source device according to a comparative example.

FIG. 18 is a rear perspective view of a semiconductor laser light source device according to a fourth embodiment.

FIG. 19 is a plan view of the semiconductor laser light source device according to the fourth embodiment.

FIG. 20 is a side view of the semiconductor laser light source device according to the fourth embodiment.

FIG. 21 is a graph representing the frequency response characteristics of the semiconductor laser light source device according to the fourth embodiment and of a semiconductor laser light source device according to a comparative example.

FIG. 22 is a rear perspective view of a semiconductor laser light source device according to a fifth embodiment.

FIG. 23 is a plan view of the semiconductor laser light source device according to the fifth embodiment.

FIG. 24 is a side view of the semiconductor laser light source device according to the fifth embodiment.

FIG. 25 is a graph representing the frequency response characteristics of the semiconductor laser light source device according to the fifth embodiment and of a semiconductor laser light source device according to a comparative example.

FIG. 26 is a rear perspective view of a semiconductor laser light source device according to a sixth embodiment.

FIG. 27 is a graph representing the frequency response characteristics of the semiconductor laser light source device according to the sixth embodiment and of a semiconductor laser light source device according to a comparative example.

### DESCRIPTION OF EMBODIMENTS

A semiconductor laser light source device according to each embodiment will be described with reference to drawings. The same reference characters are given to the same or corresponding components, and description thereof might not be repeated. In the following description, terms meaning specific positions and directions such as “up”, “down”, “front”, “back”, “left”, “right”, and “side” might be used. Those terms are used for convenience in order to make it easy to understand contents of the embodiments and do not limit positions or directions in carrying out the embodiments.

### First Embodiment

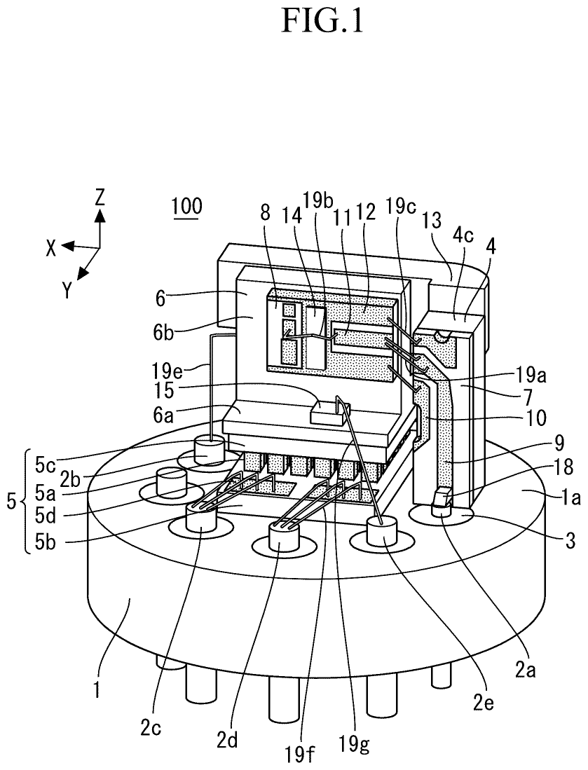

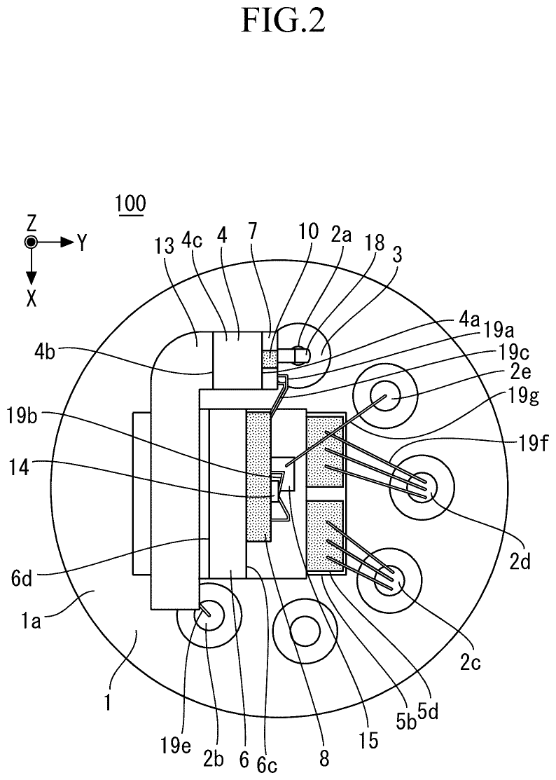

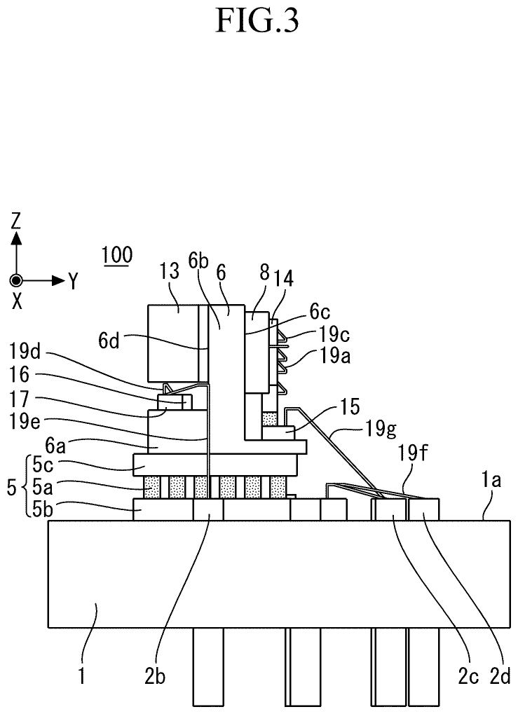

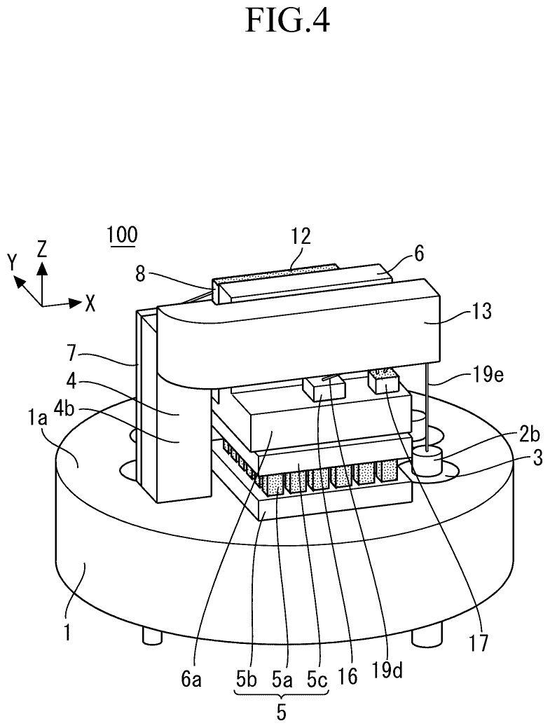

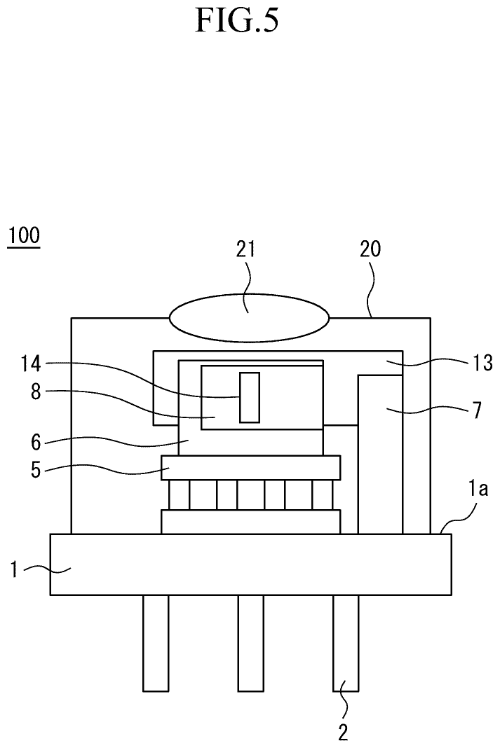

FIG. 1 is a front perspective view of a semiconductor laser light source device 100 according to a first embodiment. FIG. 2 is a plan view of the semiconductor laser light source device 100 according to the first embodiment. FIG. 3 is a side view of the semiconductor laser light source device 100 according to the first embodiment. FIG. 4 is a rear perspective view of the semiconductor laser light source device 100 according to the first embodiment. FIG. 5 is an outline diagram of the semiconductor laser light source device 100 according to the first embodiment. Note that FIGS. 1 to 4 do not illustrate a cap 20.

The semiconductor laser light source device 100 includes a metal stem 1. The metal stem 1 has a plate shape and is circular in a plan view. A plurality of lead pins 2a to 2e pass through the metal stem 1, from a main surface 1a to a surface on an opposite side to the main surface 1a. As materials of the metal stem 1 and the lead pin 2, for example, metal such as copper, iron, or stainless steel can be used. Gold plating or nickel plating may be applied to surfaces of the metal stem 1 and the lead pin 2.

Portions between the metal stem 1 and the lead pins 2a to 2e are filled with glass 3, for example. The lead pins 2a to 2e are fixed to the metal stem 1 by the glass 3. When impedance mismatching occurs, frequency response characteristics are degraded due to multiple reflections of a signal, and it becomes difficult to achieve high-speed modulation. Consequently, it is preferable that the glass 3 is formed of a material with a low dielectric constant so as to have the same impedance as that of a signal generator.

A temperature control module 5 and a first support block 4 which is electrically conductive are mounted on the main surface 1a of the metal stem 1. For example, metal such as copper, iron, or stainless steel can be used for the first support block 4. Gold plating or nickel plating may be applied to a surface of the first support block 4. Further, the first support block 4 may integrally be shaped with the metal stem 1. The first support block 4 is a rectangular cuboid, for example. A back surface, on an opposite side to an upper surface 4c, in the first support block 4 is provided on the main surface 1a of the metal stem 1. Among side surfaces which couple the upper surface 4c with the back surface of the first support block 4, a surface facing a Y-axis positive direction is a side surface 4a, and a surface facing a Y-axis negative direction is a rear surface 4b.

The temperature control module 5 has an upper surface and a back surface on an opposite side to the upper surface, and the back surface is provided on the main surface 1a of the metal stem 1. The temperature control module 5 includes a lower-side substrate 5b and an upper-side substrate 5c which are formed of AlN or the like and a plurality of thermoelectric devices 5a which are interposed between the lower-side substrate 5b and the upper-side substrate 5c and are formed of BiTe or the like, for example. The upper surface of the temperature control module 5 corresponds to an upper surface of the upper-side substrate 5c, and the back surface of the temperature control module 5 corresponds to a back surface of the lower-side substrate 5b. For example, the main surface 1a of the metal stem 1 and the lower-side substrate 5b are joined together by a joining material such as SnAgCu solder or AuSn solder, for example. The lower-side substrate 5b has a protrusion portion which protrudes to a front portion relative to the upper-side substrate 5c. This protrusion portion is provided with metallizing 5d for supplying power to the thermoelectric devices 5a. Note that the front corresponds to the Y-axis positive direction in FIG. 1.

A second support block 6 which is electrically conductive is provided on the upper surface of the temperature control module 5. The second support block 6 is formed of a metal material in which Au plating or the like is applied to a surface of metal such as copper, iron, or stainless steel, for example. The second support block 6 may be formed by coating an insulator such as a ceramic or a resin with metal. The second support block 6 has a pedestal portion 6a which is provided on the upper surface of the temperature control module 5 and a side wall portion 6b which extends upward from the pedestal portion 6a, for example. In the side wall portion 6b, a surface facing the Y-axis positive direction is a side surface 6c, and a surface facing the Y-axis negative direction is a rear surface 6d. Note that an upward direction corresponds to a Z-axis positive direction in FIG. 1.

A dielectric substrate 7 is mounted on the side surface 4a of the first support block 4. A dielectric substrate 8 is mounted on the side surface 6c of the second support block 6. The dielectric substrates 7 and 8 are formed of a ceramic material such as aluminum nitride, for example. The dielectric substrates 7 and 8 have an electric insulation function and a heat transmission function.

A signal line 9 and a ground conductor 10 are formed on the dielectric substrate 7. The signal line 9 is arranged between sides, which are orthogonal to each other, in a front surface of the dielectric substrate 7, for example. Further, the ground conductor 10 is formed on the front surface of the dielectric substrate 7 in a state where the ground conductor 10 maintains a certain interval from the signal line 9, for example. In this way, a coplanar line can be formed. The ground conductor 10 is formed from the front surface to a back surface of the dielectric substrate 7 and is, on the back surface, electrically connected with the first support block 4. The ground conductor 10 on the front surface and the back surface of the dielectric substrate 7 are electrically connected via a castellation, for example.

A signal line 11 and a ground conductor 12 are formed on the dielectric substrate 8. The ground conductor 12 is formed on a front surface of the dielectric substrate 8 in a state where the ground conductor 12 maintains a certain interval from the signal line 11, for example. The ground conductor 12 is provided from the front surface, through a side surface, and to a back surface of the dielectric substrate 8. The ground conductor 12 on the back surface side is joined to the second support block 6 and is electrically connected with the second support block 6.

A metal block 13 is provided on the rear surface 4b of the first support block 4. The metal block 13 covers at least a part of the rear surface 6d on an opposite side to the side surface 6c of the second support block 6. The metal block 13 is spaced apart from the second support block 6. The metal block 13 has a shape which is connected with the first support block 4 and is capable of not contacting with the second support block 6. The metal block 13 has an L shape or a J shape in a plan view, for example. The metal block 13 is formed of a metal material such as copper, iron, or stainless steel, for example. Au plating or the like may be applied to a surface of the metal block 13. Further, the metal block 13 may be formed by coating an insulator such as a ceramic or a resin with metal. A thickness of a portion of the metal block 13, which is opposed to the second support block 6, is 0.6 mm, for example.

A photosemiconductor chip 14 is provided on the front surface of the dielectric substrate 8. The photosemiconductor chip 14 is a semiconductor optical modulation apparatus, for example. A modulator unit of the photosemiconductor chip 14 is formed from a plurality of electro-absorption type optical modulators. The photosemiconductor chip 14 is a modulator integrated type laser diode in which electro-absorption type optical modulators using an InGaAsP-based quantum well absorption layer and a distributed feedback type laser diode are monolithically integrated together, for example. Laser light is radiated from a light emission point of the photosemiconductor chip 14 along an optical axis which is vertical to a chip end surface and parallel with a chip main surface.

A light receiving device 15, a temperature sensor 16, and a ceramic block 17 are mounted on the pedestal portion 6a of the second support block 6. As a joining material for joining the temperature sensor 16 and the ceramic block 17 to the second support block 6, for example, SnAgCu solder, AuSn solder, or the like is used. The temperature sensor 16 is a thermistor, for example. The ceramic block 17 is an AlN substrate on whose upper surface a conductor film is provided, for example. The light receiving device 15 is arranged on a Z-axis negative direction side of the photosemiconductor chip 14.

A conductive joining material 18 connects the lead pin 2a with one end of the signal line 9. The conductive joining material 18 is SnAgCu solder or AuSn solder, for example. The conductive joining material 18 may be a conductive wire. A conductive wire 19a connects another end of the signal line 9 with one end of the signal line 11. A conductive wire 19b connects another end of the signal line 11 with an EAM electrode of the photosemiconductor chip 14. A conductive wire 19c connects the ground conductor 10 with the ground conductor 12. A conductive wire 19d connects the temperature sensor 16 with the conductor film of the ceramic block 17. A conductive wire 19e connects the conductor film of the ceramic block 17 with the lead pin 2b. Conductive wires 19f connect pieces of metallizing 5d of the temperature control module 5 with the lead pins 2c and 2d. A conductive wire 19g connects the light receiving device 15 with the lead pin 2e.

The cap 20 for airtight sealing is joined to the metal stem 1. The cap 20 is electrically conductive and has a lens 21. The cap 20 is provided on the main surface 1a of the metal stem 1 and covers and airtightly seals the first support block 4, the temperature control module 5, the second support block 6, the dielectric substrates 7 and 8, the photosemiconductor chip 14, the temperature sensor 16, and so forth. Accordingly, humidity resistance and disturbance resistance of the semiconductor laser light source device 100 can be improved. The lens 21 is formed of glass such as SiO2, for example. The lens 21 collects laser light emitted from the photosemiconductor chip 14 and causes that to be incident on fibers.

When a temperature of the photosemiconductor chip 14 changes, an oscillation wavelength changes. Thus, the temperature of the photosemiconductor chip 14 has to be maintained constant. Thus, in a case where the temperature of the photosemiconductor chip 14 rises, the temperature control module 5 performs cooling, and in a case where the temperature of the photosemiconductor chip 14 lowers, the temperature control module 5 generates heat. Accordingly, the temperature of the photosemiconductor chip 14 can be set to a constant temperature. The heat generated in the photosemiconductor chip 14 is transmitted to the upper-side substrate 5c of the temperature control module 5 via the dielectric substrate 8 and the second support block 6. The temperature control module 5 absorbs the heat from the photosemiconductor chip 14. The heat absorbed by the temperature control module 5 is propagated in the Z-axis negative direction from the lower-side substrate 5b of the temperature control module 5 via the metal stem 1 and is dissipated to a lower surface side of the metal stem 1.

The temperature sensor 16 indirectly measures the temperature of the photosemiconductor chip 14. The temperature sensor 16 feeds back the measured temperature to the temperature control module 5. The temperature control module 5 performs cooling in a case where the temperature of the photosemiconductor chip 14 is high with respect to a target value and performs heat generation in a case where the temperature is low. Accordingly, the temperature of the photosemiconductor chip 14 can be stabilized.

The temperature sensor 16 is electrically connected with the lead pin 2b via the conductor film of the ceramic block 17. When the temperature sensor 16 is directly connected with the lead pin 2b by a wire, there is a possibility that an atmospheric temperature transmitted from an outside environment to the metal stem 1 flows into the temperature sensor 16 through the wire. Thus, the temperature sensor 16 might not be capable of measuring an accurate temperature. Accordingly, the ceramic block 17 is arranged between the temperature sensor 16 and the lead pin 2b, a heat quantity flowing into the temperature sensor 16 is thereby reduced, and the accurate temperature can be measured by the temperature sensor 16.

The light receiving device 15 performs O/E (optical/electronic) conversion of an optical signal to an electric signal. The electric signal is transmitted to the lead pin 2e via the connected conductive wire 19g. Although the light receiving device 15 is provided and the number of lead pins passing through the metal stem 1 is thereby increased by one, an intensity of rear surface light of the photosemiconductor chip 14 can be monitored. By feeding back this monitoring result, a driving current for the photosemiconductor chip 14 can be controlled such that an optical output becomes constant.

The electric signal input to the lead pin 2a is applied to the modulators of the photosemiconductor chip 14 via the conductive joining material 18, the signal line 9, the conductive wire 19a, the signal line 11, and the conductive wire 19b. Because the electric signal input to the lead pin 2a is electromagnetically bonded to the metal stem 1, the metal stem 1 acts as an AC ground. When the metal stem 1 acts as the AC ground, the first support block 4 and the cap 20 which are connected with the metal stem 1 also serve as AC grounds. Similarly, the ground conductor 10 and the metal block 13 which are connected with the first support block 4 also serve as AC grounds. In addition, the ground conductor 10 is connected with the ground conductor 12 via the conductive wire 19c, and the ground conductor 12 is connected with the upper-side substrate 5c of the temperature control module 5 via the second support block 6. Thus, the ground conductor 12, the second support block 6, and the temperature control module 5 also act as AC grounds.

In general, a reference potential is given to each portion from the metal stem 1 to the upper-side substrate 5c of the temperature control module 5, resonance in a band is thereby suppressed, and degradation of the frequency response characteristics is suppressed. However, actually, until the reference potential reaches from the metal stem 1 given the reference potential to the second support block 6 and the upper-side substrate 5c of the temperature control module 5, the reference potential passes via several structures and conductive wires. Thus, potentials of the second support block 6 and the upper-side substrate 5c of the temperature control module 5 might be high with respect to the reference potential. In this case, particularly in a high frequency region which exceeds 20 GHz, a signal which is propagated through a space in a package might be discharged from a member with a high potential to a member with a low potential. Specifically, there is a possibility that a signal is discharged from the second support block 6 or the upper-side substrate 5c of the temperature control module 5 toward the metal stem 1 and the first support block 4 or the cap 20, which is directly joined to the metal stem 1. This might cause resonance, and band broadening might be restricted.

On the other hand, in the present first embodiment, the metal block 13 is provided between the second support block 6 and the cap 20. The signal which is discharged from the second support block 6 and the upper-side substrate 5c of the temperature control module 5 to the space can be blocked and absorbed by the metal block 13. Consequently, resonance can be suppressed, or a frequency at which resonance occurs can be changed. Consequently, the high frequency characteristics can be improved.

In particular, in the present embodiment, the metal block 13 is arranged in the vicinity of the second support block 6 and the upper-side substrate 5c of the temperature control module 5 and is connected with the first support block 4 whose potential is extremely close to the reference potential. Accordingly, the signal which is discharged from the second support block 6 and the upper-side substrate 5c of the temperature control module 5 to the space can effectively be blocked and absorbed by the metal block 13.

Further, when seen in a vertical direction to the side surface 6c of the second support block 6, the metal block 13 is protruded from a portion of the second support block 6 on an opposite side to the first support block 4. Accordingly, the metal block 13 can cover a wide range of the rear surface 6d of the second support block 6, and a large area which is capable of absorbing the signal can be secured. Consequently, an effect of suppressing resonance can be enhanced. Note that even in arrangement where the metal block 13 is not protruded with respect to the second support block 6 in an X-axis positive direction, the effect of suppressing resonance can be obtained.

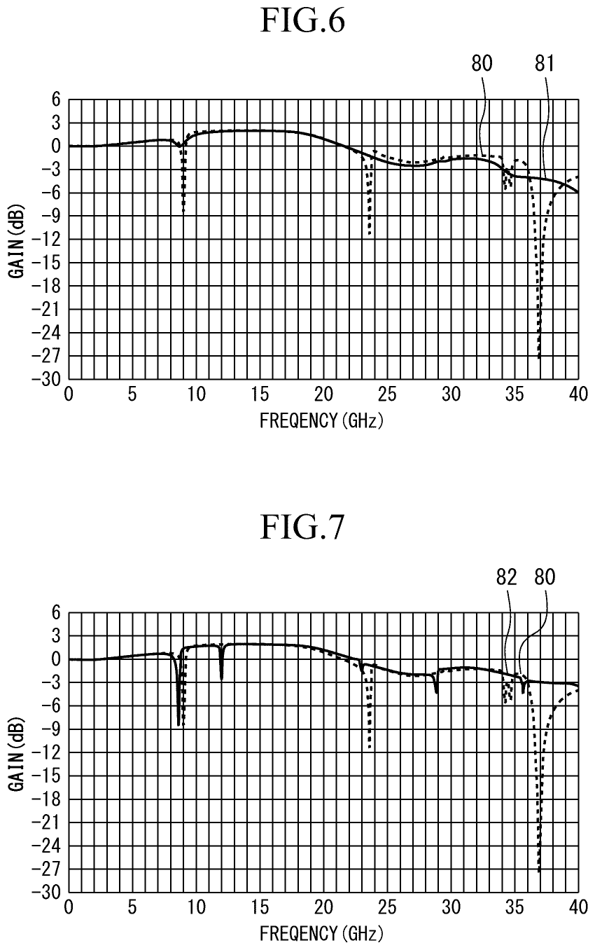

FIG. 6 is a graph representing the frequency response characteristics in cases where the cap 20 is present in a semiconductor laser light source device according to a comparative example and where no cap 20 is present. Here, the semiconductor laser light source device according to the comparative example is different from the semiconductor laser light source device 100 of the present embodiment in the point that the metal block 13 is not provided. Further, data in FIG. 6 are obtained by a three-dimensional electromagnetic field simulation. It can be understood that in a case, which is indicated by a solid line 81, where the cap 20 is omitted, compared to a case, which is indicated by a broken line 80, where the cap 20 is mounted, large drops of gain disappear. In other words, it can be understood that the drops of gain occur due to resonance with the cap 20.

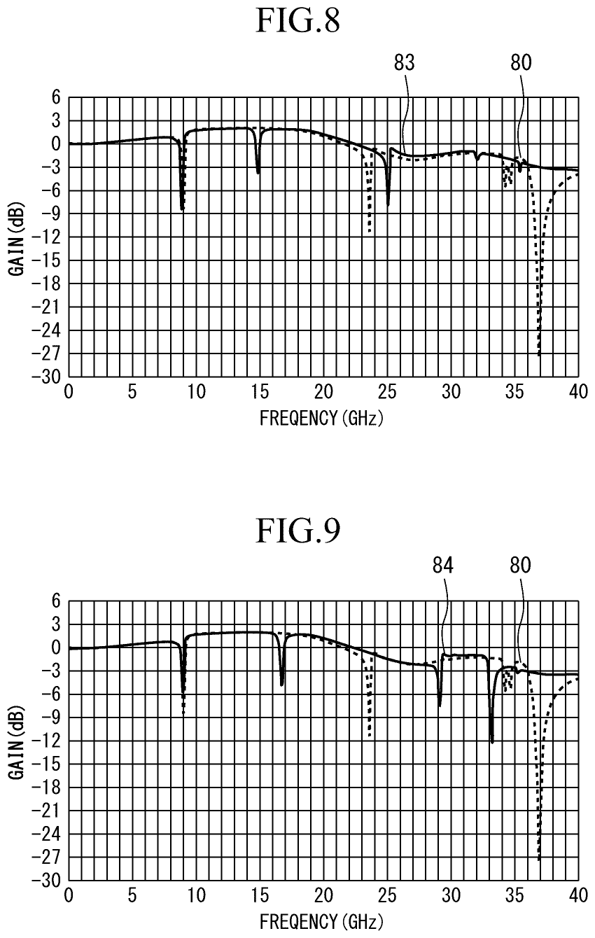

FIG. 7 is a graph representing the frequency response characteristics of the semiconductor laser light source device 100 according to the first embodiment and of the semiconductor laser light source device according to the comparative example. FIGS. 8 and 9 are graphs representing the frequency response characteristics of semiconductor laser light source devices according to modifications of the first embodiment and of the semiconductor laser light source device according to the comparative example. Data in FIG. 7 to FIG. 9 are also obtained by the three-dimensional electromagnetic field simulation. In FIG. 7, characteristics of the present embodiment are indicated by a solid line 82, and characteristics of the comparative example are indicated by a broken line 80. FIG. 7 illustrates a simulation result in a case where a length of the metal block 13 in an X-axis direction is made longer than a length of the second support block 6 in the X-axis direction and an area in which the metal block 13 covers the rear surface 6d of the second support block 6 is made as large as possible. In the present embodiment, it can be observed that large drops of gain at 24 GHz and 37 GHz in the comparative example disappear.

A solid line 83 in FIG. 8 indicates a simulation result in a case where the metal block 13 is made shorter in the X-axis direction than the present embodiment. Specifically, the area, which is covered by the metal block 13, in the rear surface 6d of the second support block 6 is set to 50% of the present embodiment. A solid line 84 in FIG. 9 indicates a simulation result in a case where the area, which is covered by the metal block 13, in the rear surface 6d of the second support block 6 is set to 10% of the present embodiment. In each of the modifications illustrated in FIGS. 8 and 9, a large drop of gain at 37 GHz disappears. In other words, it can be understood that even in a case where a part of the rear surface 6d of the second support block 6 is exposed from the metal block 13, the effect of suppressing resonance can also be obtained.

Note that the metal block 13 and the second support block 6 may contact with each other. In this case also, an improvement in the frequency response characteristics is possible. In this case, there is a possibility that heat from the outside environment which flows into the metal stem 1 flows into the second support block 6 via the first support block 4 and the metal block 13. Thus, there is a possibility that the heat is also transmitted to the photosemiconductor chip 14 and the temperature sensor 16 and temperature control by the temperature control module 5 becomes difficult. Thus, it is desirable that the metal block 13 and the second support block 6 should not contact with each other.

Further, the lead pin 2a connected with the signal line 9 has an inner lead portion which is projected from an upper surface of the metal stem 1. An inductance component is reduced as a length of the inner lead portion is made shorter, and loss due to reflection of the signal in the inner lead portion can be reduced. Thus, a wide pass band can be secured. Further, in order to obtain a maximum voltage amplitude from the signal generator, a matching resistance may be provided on a front surface of the dielectric substrate 8 and may be connected in parallel with the photosemiconductor chip 14. Further, the metal block 13 may integrally be shaped with the first support block 4.

These modifications can be applied, as appropriate, to semiconductor laser light source devices according to the following embodiments. Note that the semiconductor laser light source devices according to the following embodiments are similar to that of the first embodiment in many respects, and thus differences between the semiconductor laser light source devices according to the following embodiments and that of the first embodiment will be mainly described below.

### Second Embodiment

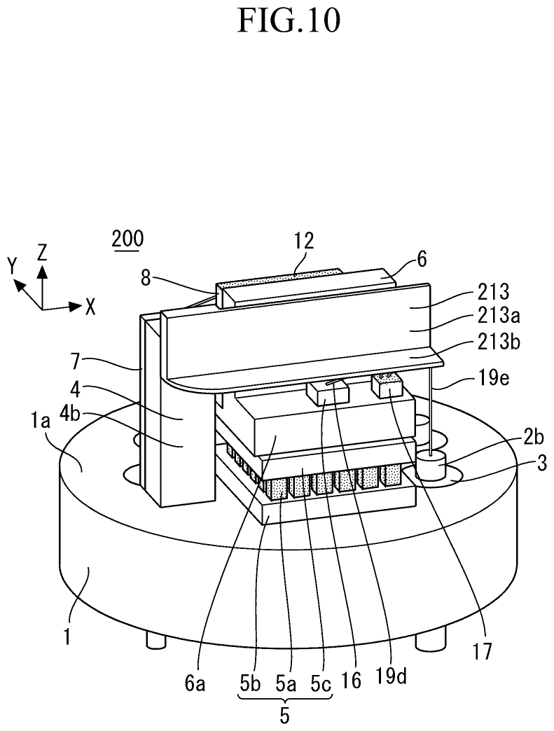

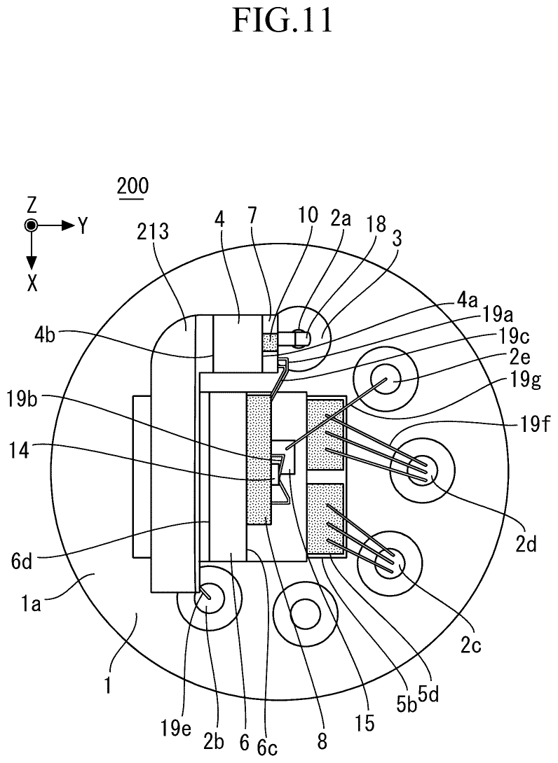

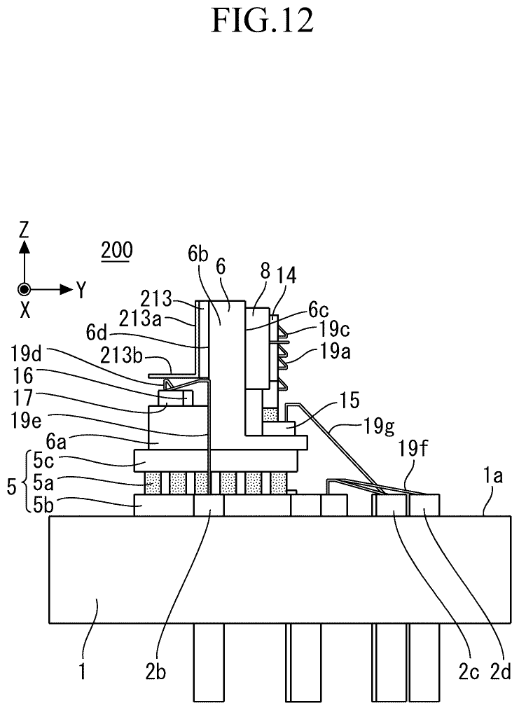

FIG. 10 is a rear perspective view of a semiconductor laser light source device 200 according to a second embodiment. FIG. 11 is a plan view of the semiconductor laser light source device 200 according to the second embodiment. FIG. 12 is a side view of the semiconductor laser light source device 200 according to the second embodiment. The present embodiment is different from the first embodiment in the point that a metal plate 213 is provided instead of the metal block 13. Other structures are similar to structures of the first embodiment.

The metal plate 213 has a first portion 213a which covers at least a part of the rear surface 6d of the second support block 6 and a second portion 213b which is bent from the first portion 213a and covers at least a part of the pedestal portion 6a. A cross-sectional view of the metal plate 213 as seen in the X-axis direction is an L shape, for example. The metal plate 213 is thin compared to the metal block 13. A thickness of each of the first portion 213a and the second portion 213b of the metal plate 213 is 0.05 mm, for example. It is preferable that the thickness of each of the first portion 213a and the second portion 213b of the metal plate 213 be 0.2 mm or smaller. Similarly to the first embodiment, the metal plate 213 is provided on the rear surface 4b of the first support block 4 and is spaced apart from the second support block 6.

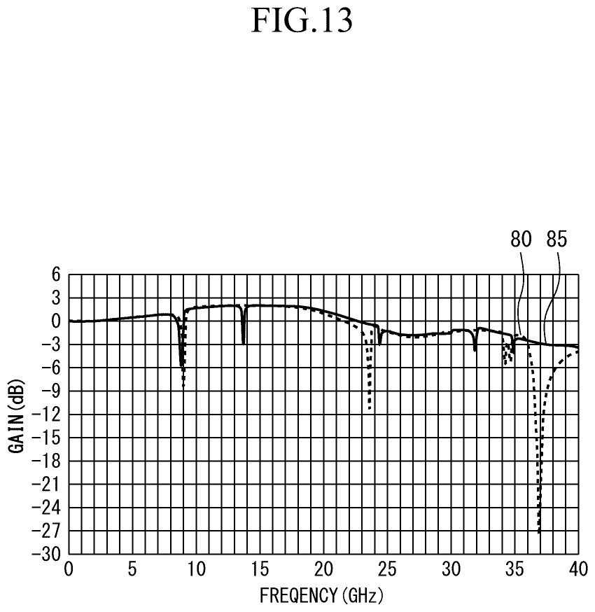

FIG. 13 is a graph representing the frequency response characteristics of the semiconductor laser light source device 200 according to the second embodiment and of a semiconductor laser light source device according to a comparative example. The semiconductor laser light source device according to the comparative example is different from the semiconductor laser light source device 200 of the present embodiment in the point that the metal plate 213 is not provided. In a simulation result illustrated in FIG. 13, it can be observed that in the characteristics of the present embodiment, which are indicated by a solid line 85, large drops of gain at 24 GHz and 37 GHz in the characteristics of the comparative example, which are indicated by the broken line 80, disappear. In such a manner, in the present embodiment, the high frequency characteristics can also be improved.

Further, the metal plate 213 of the present embodiment has a smaller size than the metal block 13 in the first embodiment. Thus, costs can be suppressed.

### Third Embodiment

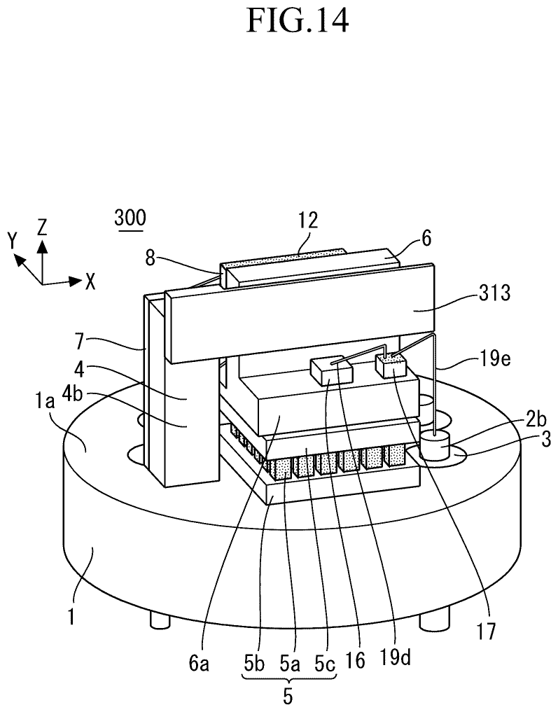

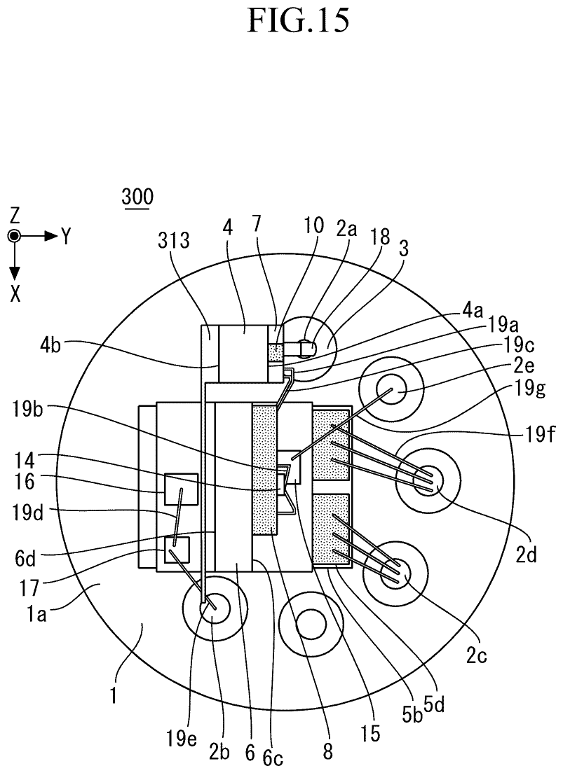

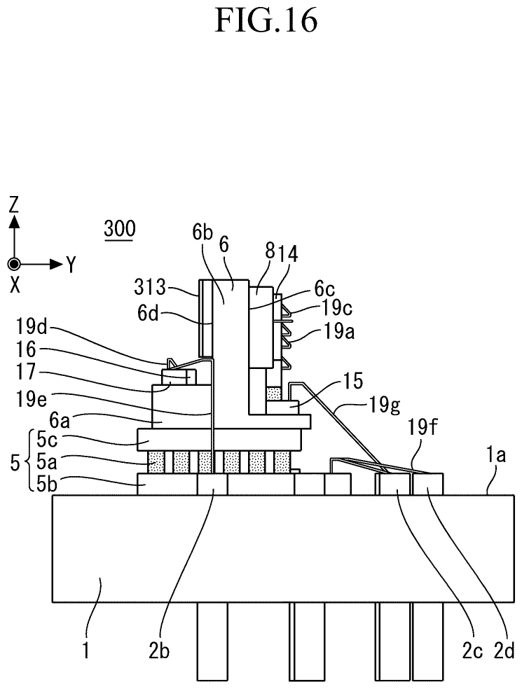

FIG. 14 is a rear perspective view of a semiconductor laser light source device 300 according to a third embodiment. FIG. 15 is a plan view of the semiconductor laser light source device 300 according to the third embodiment. FIG. 16 is a side view of the semiconductor laser light source device 300 according to the third embodiment. The present embodiment is different from the first embodiment in the point that a metal plate 313 is provided instead of the metal block 13. Other structures are similar to the structures of the first embodiment.

A cross-sectional view of the metal plate 313 as seen in the X-axis direction is an I shape, for example. The metal plate 313 is thin compared to the metal block 13. A thickness of a portion of the metal plate 313, which is opposed to the second support block 6, is 0.05 mm, for example. Similarly to the first embodiment, the metal plate 313 is provided on the rear surface 4b of the first support block 4 and is spaced apart from the second support block 6.

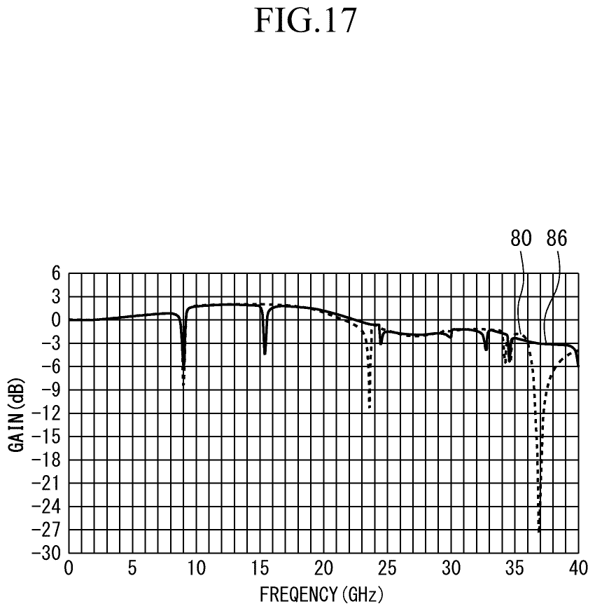

FIG. 17 is a graph representing the frequency response characteristics of the semiconductor laser light source device 300 according to the third embodiment and of a semiconductor laser light source device according to a comparative example. The semiconductor laser light source device according to the comparative example is different from the semiconductor laser light source device 300 of the present embodiment in the point that the metal plate 313 is not provided. In a simulation result illustrated in FIG. 17, it can be observed that in the characteristics of the present embodiment, which are indicated by a solid line 86, large drops of gain at 24 GHz and 37 GHz in the characteristics of the comparative example, which are indicated by the broken line 80, disappear. In such a manner, in the present embodiment, the high frequency characteristics can also be improved.

Further, the metal plate 313 has a much smaller size than the metal plate 213 in the second embodiment. Thus, costs can further be suppressed. Further, compared to the metal block 13 and the metal plate 213, the metal plate 313 has a small space occupancy rate in an internal portion of the semiconductor laser light source device 300. Thus, the metal plate 313 is less likely to interfere with other members, and ease of assembly can thereby be improved. When the thickness of the portion of the metal plate 313, which is opposed to the second support block 6, is 0.2 mm or smaller, interference between members can particularly be hindered from occurring.

Note that in each of the second and third embodiment, similarly to the first embodiment, even in arrangement where each of the metal plates 213 and 313 is not protruded with respect to the second support block 6 in the X-axis positive direction, the effect of suppressing resonance can also be obtained. Further, as a distance between the second support block 6 and the metal plate 313 becomes longer, a positional relationship between the second support block 6 and the metal plate 313 becomes closer to a positional relationship between the second support block 6 and the cap 20 according to the comparative example. Thus, it is preferable that the metal plate 313 be as close as possible to the second support block 6.

### Fourth Embodiment

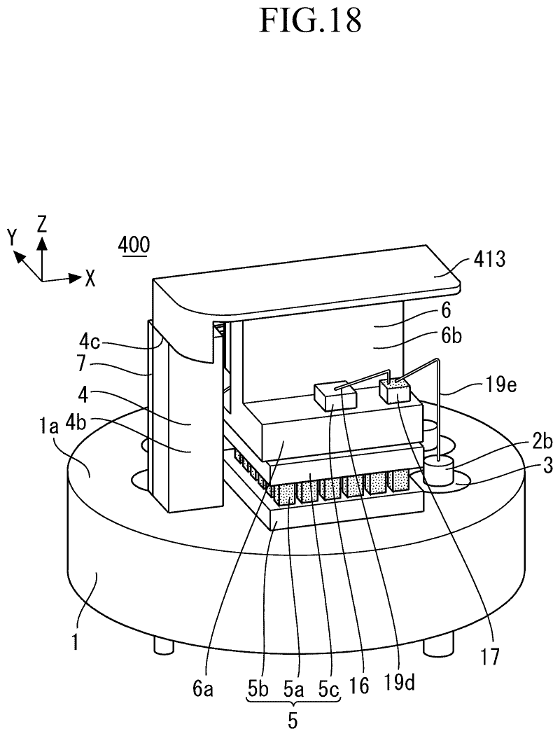

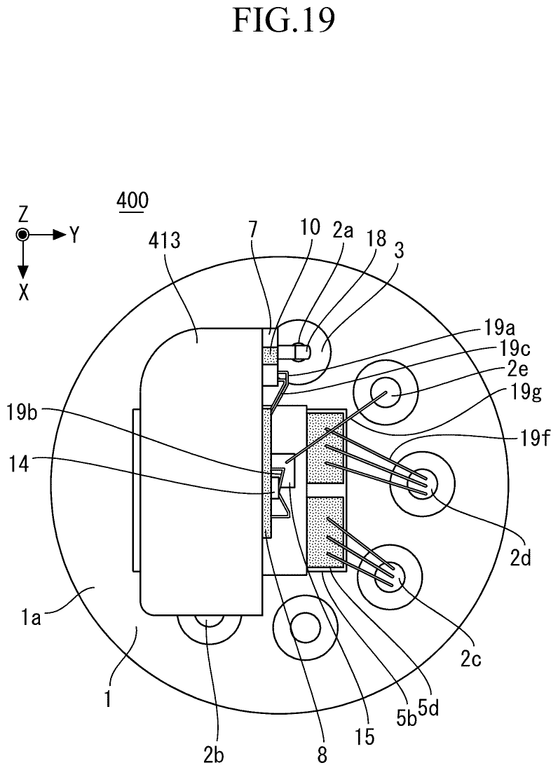

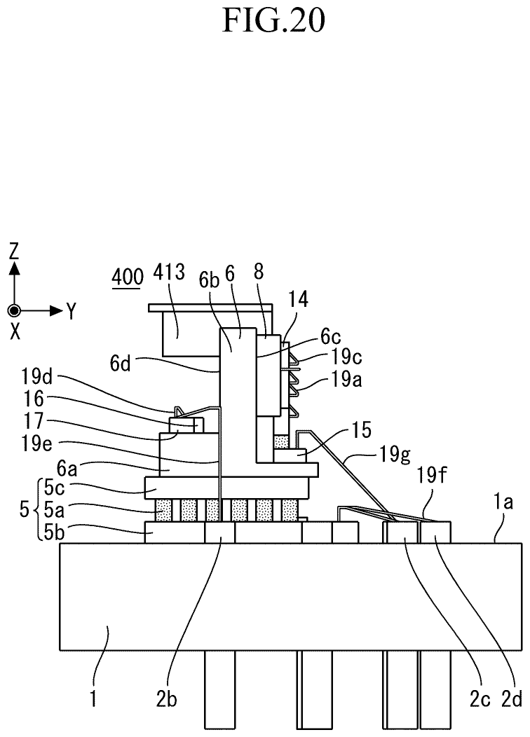

FIG. 18 is a rear perspective view of a semiconductor laser light source device 400 according to a fourth embodiment. FIG. 19 is a plan view of the semiconductor laser light source device 400 according to the fourth embodiment. FIG. 20 is a side view of the semiconductor laser light source device 400 according to the fourth embodiment. The present embodiment is different from the first embodiment in the point that a metal block 413 is provided instead of the metal block 13. Other structures are similar to the structures of the first embodiment.

The metal block 413 is connected with the upper surface 4c of the first support block 4. The metal block 413 extends from the first support block 4 to a portion directly above the second support block 6. As illustrated in FIG. 19, the metal block 413 is arranged so as not to block laser light from the photosemiconductor chip 14. In other words, the metal block 413 is arranged while avoiding a portion directly above the photosemiconductor chip 14. Further, in order to absorb a larger amount of the signal discharged from the second support block 6, it is desirable that the metal block 413 be as large as possible in a range in which the laser light is not blocked.

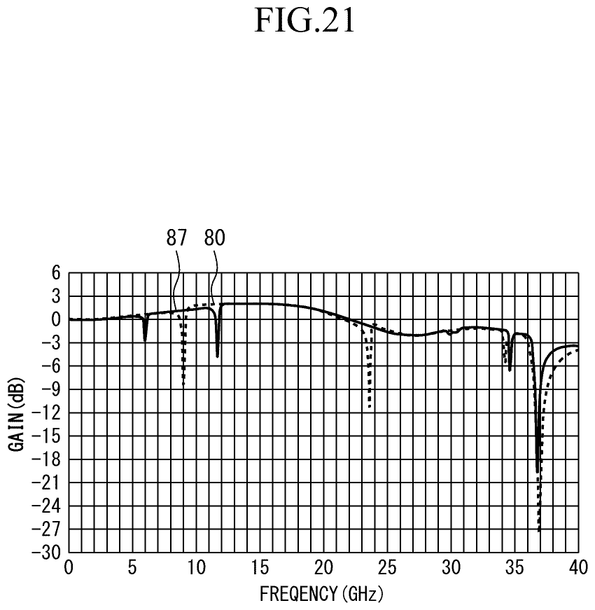

FIG. 21 is a graph representing the frequency response characteristics of the semiconductor laser light source device 400 according to the fourth embodiment and of a semiconductor laser light source device according to a comparative example. The semiconductor laser light source device according to the comparative example is different from the semiconductor laser light source device 400 of the present embodiment in the point that the metal block 413 is not provided. In a simulation result illustrated in FIG. 21, it can be observed that in the characteristics of the present embodiment, which are indicated by a solid line 87, a large drop of gain at 24 GHz in the characteristics of the comparative example, which are indicated by the broken line 80, disappears. Further, in the present embodiment, although a drop of gain at 37 GHz in the characteristics of the comparative example does not disappear, it can be observed that the drop is decreased. In such a manner, in the present embodiment also, resonance can be suppressed, and the high frequency characteristics can be improved.

### Fifth Embodiment

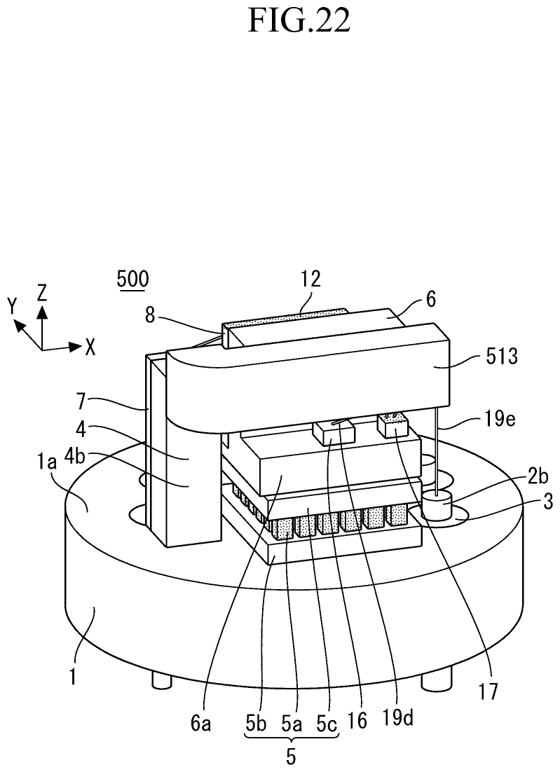

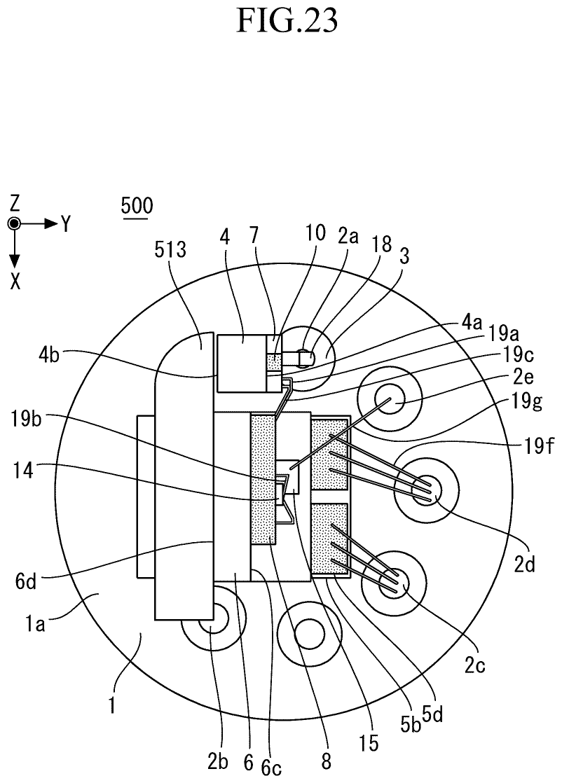

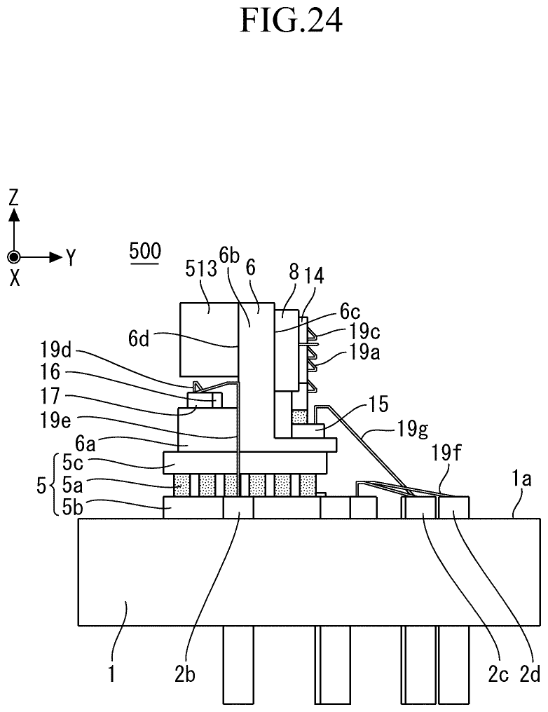

FIG. 22 is a rear perspective view of a semiconductor laser light source device 500 according to a fifth embodiment. FIG. 23 is a plan view of the semiconductor laser light source device 500 according to the fifth embodiment. FIG. 24 is a side view of the semiconductor laser light source device 500 according to the fifth embodiment. The present embodiment is different from the first embodiment in the point that a metal block 513 is provided instead of the metal block 13. Other structures are similar to the structures of the first embodiment. The metal block 513 is provided on the rear surface 6d of the second support block 6. The metal block 513 covers at least a part of the rear surface 4b of the first support block 4. The metal block 513 is spaced apart from the first support block 4.

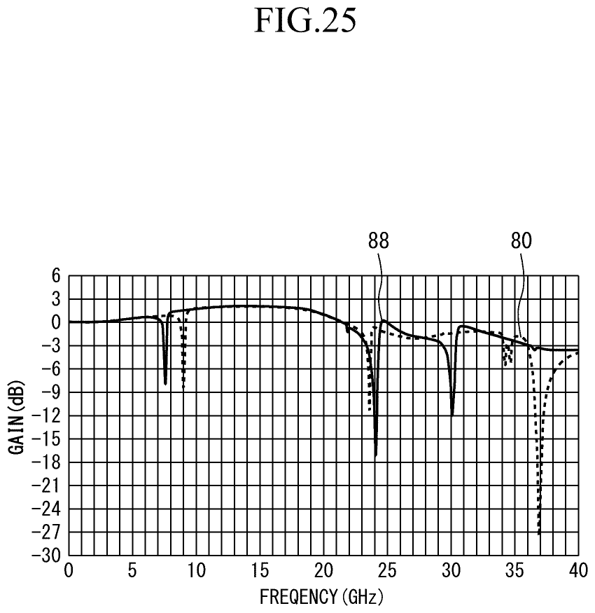

FIG. 25 is a graph representing the frequency response characteristics of the semiconductor laser light source device 500 according to the fifth embodiment and of a semiconductor laser light source device according to a comparative example. The semiconductor laser light source device according to the comparative example is different from the semiconductor laser light source device 500 of the present embodiment in the point that the metal block 513 is not provided. In a simulation result illustrated in FIG. 25, it can be observed that in the characteristics of the present embodiment, which are indicated by a solid line 88, a large drop of gain at 37 GHz in the characteristics of the comparative example, which are indicated by the broken line 80, disappears. In such a manner, in the present embodiment, the high frequency characteristics can also be improved.

In the present embodiment, it can be assumed that a distance between the second support block 6 and the cap 20, which serves as a cause of resonance, is changed by the metal block 513. Thus, similarly to the first embodiment, the effect of suppressing resonance can be obtained.

Further, the metal block 513 is opposed to the rear surface 4b of the first support block 4. Accordingly, a distance between the second support block 6 and metal block 513 and the first support block 4, which is close to the reference potential, can be made shorter. The signal which is discharged from the second support block 6 to the space is attracted to the reference potential. Thus, in arrangement of the present embodiment, the signal discharged from the second support block 6 can easily be absorbed by the first support block 4. In other words, the signal which is discharged from the second support block 6 to the cap 20 can be reduced, and resonance can be suppressed.

Further, it can be assumed that a capacitor is formed from the metal block 513 or the second support block as a discharge source of the signal, the first support block 4 serving as a ground, and air between both of those. Thus, the metal block 513 and the first support block 4 are made as close as possible, and a capacitance component which serves as a cause of resonance can thereby be made small.

### Sixth Embodiment

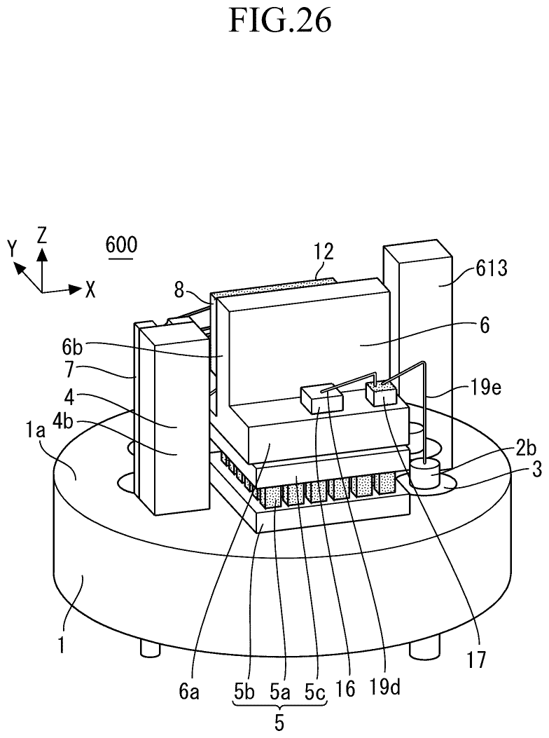

FIG. 26 is a rear perspective view of a semiconductor laser light source device 600 according to a sixth embodiment. The present embodiment is different from the first embodiment in the point that a metal block 613 is provided instead of the metal block 13. Other structures are similar to the structures of the first embodiment. The metal block 613 is provided on the main surface 1a of the metal stem 1. The metal block 613 is provided on an opposite side to the first support block 4 with respect to the second support block 6. The metal block 613 is spaced apart from the second support block 6.

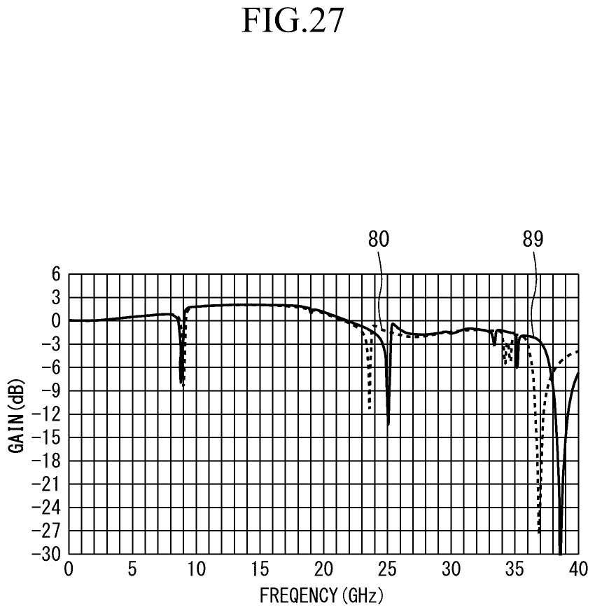

FIG. 27 is a graph representing the frequency response characteristics of the semiconductor laser light source device 600 according to the sixth embodiment and of a semiconductor laser light source device according to a comparative example. The semiconductor laser light source device according to the comparative example is different from the semiconductor laser light source device 600 of the present embodiment in the point that the metal block 613 is not provided. In a simulation result illustrated in FIG. 27, it can be observed that in the characteristics of the present embodiment, which are indicated by a solid line 89, large drops of gain at 24 GHz and 37 GHz in the characteristics of the comparative example, which are indicated by the broken line 80, are moved to a high band side. In other words, in the present embodiment, it can be observed that band broadening occurs to the frequency response characteristics. In such a manner, in the present embodiment also, resonance can be suppressed, and the high frequency characteristics can be improved.

Arrangement and shapes of the metal blocks which are illustrated in the first to sixth embodiments are examples and are not restrictive. The signal is discharged from the second support block 6 in all directions. Thus, the effect of suppressing resonance can be obtained by placing the metal block in any direction with respect to the second support block 6.

Note that the technical features described in the above embodiments may be combined as appropriate.

### REFERENCE SIGNS LIST

1 metal stem, la main surface, 2 lead pin, 2a-2e lead pin, 3 glass, 4 first support block, 4a side surface, 4b rear surface, 4c upper surface, 5 temperature control module, 5a thermoelectric device, 5b lower-side substrate, 5c upper-side substrate, 5d metallizing, 6 second support block, 6a pedestal portion, 6b side wall portion, 6c side surface, 6d rear surface, 7 dielectric substrate, 8 dielectric substrate, 9 signal line, 10 ground conductor, 11 signal line, 12 ground conductor, 13 metal block, 14 photosemiconductor chip, 15 light receiving device, 16 temperature sensor, 17 ceramic block, 18 conductive joining material, 19a-19g conductive wire, 20 cap, 21 lens, 100 semiconductor laser light source device, 200 semiconductor laser light source device, 213 metal plate, 213a first portion, 213b second portion, 300 semiconductor laser light source device, 313 metal plate, 400 semiconductor laser light source device, 413 metal block, 500 semiconductor laser light source device, 513 metal block, 600 semiconductor laser light source device, 613 metal block

1. A semiconductor laser light source device comprising:
a metal stem;
a first support block which is provided on a main surface of the metal stem and is electrically conductive;
a temperature control module which has an upper surface and a back surface on an opposite side to the upper surface, the back surface being provided on the main surface of the metal stem;
a second support block which is provided on the upper surface of the temperature control module and is electrically conductive;
a first substrate which is provided on a first side surface of the first support block and in which a signal line is formed;
a second substrate which is provided on a second side surface of the second support block and in which a signal line is formed;
a photosemiconductor chip which is provided on the second substrate;
an electrically conductive cap which is provided on the main surface of the metal stem and covers the first support block, the temperature control module, the second support block, the first substrate, the second substrate, and the photosemiconductor chip; and
a metal block which is provided between the second support block and the cap, wherein
the metal block is provided on the first support block, and
the metal block covers at least a part of a second rear surface on an opposite side to the second side surface of the second support block.

2. (canceled)

3. The semiconductor laser light source device according to claim 1, wherein the metal block is spaced apart from the second support block.

4. (canceled)

5. The semiconductor laser light source device according to claim 1, wherein when seen in a vertical direction to the second side surface of the second support block, the metal block is protruded from a portion of the second support block on an opposite side to the first support block.

6. The semiconductor laser light source device according to claim 1, wherein
the second support block has a pedestal portion which is provided on the upper surface of the temperature control module and a side wall portion which extends upward from the pedestal portion and includes the second side surface and the second rear surface, and
the metal block has a first portion which covers at least a part of the second rear surface of the second support block and a second portion which is bent from the first portion and covers at least a part of the pedestal portion.

7. The semiconductor laser light source device according to claim 1, wherein the metal block is a metal plate with a thickness of 0.2 mm or smaller.

8. A semiconductor laser light source device comprising:
a metal stem;
a first support block which is provided on a main surface of the metal stem and is electrically conductive;
a temperature control module which has an upper surface and a back surface on an opposite side to the upper surface, the back surface being provided on the main surface of the metal stem;
a second support block which is provided on the upper surface of the temperature control module and is electrically conductive;
a first substrate which is provided on a first side surface of the first support block and in which a signal line is formed;
a second substrate which is provided on a second side surface of the second support block and in which a signal line is formed;
a photosemiconductor chip which is provided on the second substrate;
an electrically conductive cap which is provided on the n surface of the metal stem and covers the first support block, the temperature control module, the second support block, the first substrate, the second substrate, and the photosemiconductor chip, and
a metal block which is provided between the second support block and the cap wherein
the metal block is provided on the first support block, and
the metal block extends from the first support block to a portion directly above the second support block.

9. (canceled)

10. (canceled)

11. A semiconductor laser light source device comprising:
a metal stem;
a first support block which is provided on a main surface of the metal stem and is conductive;
a temperature control module which has an upper surface and a back surface on an opposite side to the upper surface, the back surface being provided on the main surface of the metal stem;
a second support block which is provided on of the temperature control module and is electrically conductive;
a first substrate which is provided on a first side surface of the first support block and in which a signal line is formed;
a second substrate which is provided on a second side surface of the second support block and in which a signal line is formed,
a photosemiconductor chip which is provided on the second substrate;
an electrically conductive cap which is provided on the main surface of the metal stem and covers the first support block, the temperature control module, the second support block, the first substrate, the second substrate, and the photosemiconductor chip, and
a metal block which is provided between the second support block and the cap, wherein
the metal block is provided on a second rear surface on an opposite side to the second side surface of the second support block, and
the metal block covers at least a part of a first rear surface on an opposite side to the first side surface of the first support block.

12. The semiconductor laser light source device according to claim 11, wherein the metal block is spaced apart from the first support block.

13. (canceled)

14. A semiconductor laser light source device comprising:
a metal stem,
a first support block which is provided on a tip surface of the metal stem and is electrically conductive;
a temperature control module which has an upper surface and a back surface on an opposite side to the upper surface, the back surface being provided on the main surface of the metal stem;
a second support block which is provided on the upper surface of the temperature control module and is electrically conductive;
a first substrate which is provided on a first side surface of the first support block and in which a signal line is formed,
a second substrate which is provided on a second side surface of the second support block and in which a signal line is formed;
a photosemiconductor chip which is provided on the second substrate;
an electrically conductive cap which is provided on the main surface of the metal stem and covers the first support block, the temperature control module, the second support block, the first substrate, the second substrate, and the photosemiconductor chip; and
a metal block which is provided between the second support block and the cap, wherein
the metal block is provided on the main surface of the metal stem, and
the metal block is provided on an opposite side to the first support block with respect to the second support block.

15. The semiconductor laser light source device according to claim 14, wherein the metal block is spaced apart from the second support block.

16. The semiconductor laser light source device according to any claim 1, wherein
the first substrate is provided with a ground conductor which is electrically connected with the first support block, and
the second substrate is provided with a ground conductor which is electrically connected with the second support block.

17. The semiconductor laser light source device according to claim 1, comprising:
a lead pin which passes through the metal stem, from the main surface to a surface on an opposite side to the main surface;
a ceramic block which is provided on the second support block and has a conductor film; and
a temperature sensor which is provided on the second support block and is electrically connected with the lead pin via the ceramic block.

18. The semiconductor laser light source device according to claim 8, wherein
the first substrate is provided with a ground conductor which is electrically connected with the first support block, and
the second substrate is provided with a ground conductor which is electrically connected with the second support block.

19. The semiconductor laser light source device according to claim 11, wherein
the first substrate is provided with a ground conductor which is electrically connected with the first support block, and
the second substrate is provided with a ground conductor which is electrically connected with the second support block.

20. The semiconductor laser light source device according to claim 14, wherein
the first substrate is provided with a ground conductor which is electrically connected with the first support block, and
the second substrate is provided with a ground conductor which is electrically connected with the second support block.

21. The semiconductor laser light source device according to claim 8, comprising:
a lead pin which passes through the metal stem, from the main surface to a surface on an opposite side to the main surface;
a ceramic block which is provided on the second support block and has a conductor film; and
a temperature sensor which is provided on the second support block and is electrically connected with the lead pin via the ceramic block.

22. The semiconductor laser light source device according to claim 11, comprising:
a lead pin which passes through the metal stem, from the main surface to a surface on an opposite side to the main surface;
a ceramic block which is provided on the second support block and has a conductor film; and
a temperature sensor which is provided on the second support block and is electrically connected with the lead pin via the ceramic block.

23. The semiconductor laser light source device according to claim 14, comprising:
a lead pin which passes through the metal stem, from the main surface to a surface on an opposite side to the main surface;
a ceramic block which is provided on the second support block and has a conductor film; and
a temperature sensor which is provided on the second support block and is electrically connected with the lead pin via the ceramic block.
